(19) United States
(12) Patent Application Publication
(10) Pub. No.: US 2024/0154406 A1
(43) Pub. Date: May 9, 2024

(54) SYMMETRIC RADIO FREQUENCY (RF) ELECTROSTATIC DISCHARGE (ESD) DISSIPATION SWITCH

(71) Applicant: QUALCOMM Incorporated, San Diego, CA (US)

(72) Inventors: George Pete IMTHURN, San Diego, CA (US); Woojin CHOI, San Diego, CA (US); Maurice Adrianus DE JONGH, Nijmegen (NL); Jeffrey Donald MILLER, San Diego, CA (US); Qingqing LIANG, San Diego, CA (US)

(21) Appl. No.: 17/983,261

(22) Filed: Nov. 8, 2022

(51) Int. Cl. H02H 9/04

(52) U.S. Cl. CPC H02H 9/046

(57) ABSTRACT

A radio frequency (RF) device is described. The RF device includes a first RF switch coupled in series to a first RF port and coupled in parallel to an RF common (RFC) port. The RF device also includes an electrostatic discharge (ESD) dissipation switch coupled to the RF common port. The ESD dissipation switch includes a switch field effect transistor (FET). The switch FET includes a gate on an active layer of a substrate, and a symmetric silicide area block (SAB) on a first sidewall spacer and a second sidewall spacer, opposite the first sidewall spacer, and on a gate surface of the gate, opposite the active layer of the substrate.

### TECHNICAL FIELD

The present disclosure generally relates to integrated circuits (ICs). More specifically, aspects of the present disclosure relate to a symmetric radio frequency (RF) electrostatic discharge (ESD) dissipation switch.

### BACKGROUND

The design complexity of mobile radio frequency (RF) chips (e.g., mobile RF transceivers) is complicated by added circuit functions for supporting communications enhancements. Designing mobile RF transceivers may include using semiconductor on insulator (SOI) technology. SOI technology replaces conventional semiconductor (e.g., silicon) substrates with a layered semiconductor-insulator-semiconductor substrate for reducing parasitic device capacitance and improving performance. SOI-based devices differ from conventional, silicon-built devices because a silicon junction is above an electrical isolator, typically a buried oxide (BOX) layer.

In practice, high performance RF switches are manufactured using SOI substrates. A high performance RF switch is generally characterized by a high breakdown voltage and a low bipolar gain. Unfortunately, these RF switch performance parameters can affect the response of an RF switch to an electrostatic discharge (ESD) pulse. In particular, techniques that improve a breakdown voltage in RF switches negatively affect a tolerance of the RF switch to ESD events. Techniques for reducing a susceptibility of high performance RF switches to ESD damage are desired.

### SUMMARY

A radio frequency (RF) device is described. The RF device includes a first RF switch coupled in series to a first RF port and coupled in parallel to an RF common (RFC) port. The RF device also includes an electrostatic discharge (ESD) dissipation switch coupled to the RF common port. The ESD dissipation switch includes a switch field effect transistor (FET). The switch FET includes a gate on an active layer of a substrate, and a symmetric silicide area block (SAB) on a first sidewall spacer and a second sidewall spacer, opposite the first sidewall spacer, and on a gate surface of the gate, opposite the active layer of the substrate.

A method for constructing a radio frequency (RF) device having a symmetric RF electrostatic discharge (ESD) dissipation switch is described. The method includes forming a switch field effect transistor (FET) including a gate on an active layer of a substrate. The method also includes depositing an oxide layer on the switch FET and on a surface of the active layer of the substrate. The method further includes patterning the oxide layer to expose portions of the active layer of the substrate to form a symmetric silicide area block (SAB) on the gate and on exposed portions of the active layer of the substrate proximate sidewalls of the gate. The method also includes forming source/drain silicide regions on exposed portions of the active layer of the substrate, adjacent to the symmetric SAB. The method further includes forming source/drain contacts to the source/drain silicide regions.

This has outlined, rather broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for carrying out the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is a schematic diagram of a wireless device having a wireless local area network module and a radio frequency (RF) front end module for a chipset.

FIG. 2 shows a cross-sectional view of a radio frequency (RF) integrated circuit (RFIC), including an RF silicon on insulator (SOI) device.

FIG. 3A is a schematic diagram illustrating a switch field effect transistor (FET).

FIG. 3B is a schematic diagram illustrating a switch field effect transistor (FET) having an asymmetric silicide area block (SAB).

FIGS. 4A-4J are schematic drawings illustrating a symmetric radio frequency (RF) electrostatic discharge (ESD) dissipation switch and a process for forming the symmetric RF ESD dissipation switch, according to aspects of the present disclosure.

FIG. 5 is a schematic diagram illustrating a layout view of a multi-finger symmetric radio frequency (RF) electrostatic discharge (ESD) dissipation switch, according to aspects of the present disclosure.

FIG. 6 is a schematic diagram further illustrating the connection between the body contact and a gate contact of the multi-finger symmetric radio frequency (RF) electrostatic discharge (ESD) dissipation switch of FIG. 5, in accordance with aspects of the present disclosure.

FIG. 7 is a schematic diagram illustrating a radio frequency (RF) device, including RF switches and symmetric RF electrostatic discharge (ESD) detection devices, in accordance with aspects of the present disclosure.

FIG. 8 is a process flow diagram illustrating a method for constructing a radio frequency (RF) device having a symmetric RF electrostatic discharge (ESD) detection device, according to an aspect of the present disclosure.

FIG. 9 is a block diagram showing an exemplary wireless communications system in which a configuration of the present disclosure may be advantageously employed.

FIG. 10 is a block diagram illustrating a design workstation used for circuit, layout, and logic design of a semiconductor component, according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR,” and the use of the term “or” is intended to represent an “exclusive OR.” As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

Mobile radio frequency (RF) chips (e.g., mobile RF transceivers) have migrated to a deep sub-micron process node due to cost and power consumption considerations. The design complexity of mobile RF chips, including mobile RF transceivers, is complicated by added circuit functions for supporting communications enhancements. Designing mobile RF transceivers may include using semiconductor on insulator technology. Semiconductor on insulator (SOI) technology replaces conventional semiconductor (e.g., silicon) substrates with a layered semiconductor-insulator-semiconductor substrate for reducing parasitic device capacitance and improving performance.

SOI-based devices differ from conventional, silicon-built devices because a silicon junction is above an electrical isolator, typically a buried oxide (BOX) layer, which defines the distance between the active device and the SOI substrate. That is, device performance is degraded by increasing a proximity of the active device and the SOI substrate in future process nodes. The active devices on an SOI layer may include high performance transistors. For example, high performance RF switch technologies are currently manufactured using SOI substrates. An RF front end (RFFE) may rely on these high performance RF switch technologies for successful operation.

A process for fabricating an RFFE, therefore, involves the costly integration of an SOI wafer for supporting these high performance RF switch technologies. In practice, a high performance RF switch manufactured using an SOI substrate is generally characterized by a high breakdown voltage and a low bipolar gain. Unfortunately, these RF switch performance parameters can affect the response of an RF switch to an electrostatic discharge (ESD) pulse. In particular, techniques that improve a breakdown voltage in RF switches negatively affect a tolerance of the RF switch ESD events.

For example, IEC 61000-4-2 is an electrostatic discharge (ESD) immunity standard from the International Electrotechnical Commission (IEC). As used in the mobile phone industry, the IEC 61000-4-2 standard is designed to test immunity from humans touching an antenna and damaging a radio frequency (RF) front end of a mobile phone. The IEC 61000-4-2 standard differs from the human-body model (HBM) and the charged-device (CDC) model because the IEC 61000-4-2 standard involves higher frequency components and lower series resistance relative to the HBM and CDC models. In particular, testing according to the IEC 61000-4-2 standard is performed with both positive and negative polarity pulses applied to the RF ports of the RF front end of a mobile phone.

Techniques for reducing a susceptibility of high performance RF switches to ESD damage are desired. In practice, a protection circuit composed of a shunt inductor is implemented in mobile phones for supporting testing according to the IEC 61000-4-2 standard. In operation, a small inductance causes some RF signal loss, which is detrimental for radio sensitivity. As a result, customers specify a large inductance in the RF front end of mobile devices. Unfortunately, a large inductance can lead to resonance (in the RF front end of these mobile devices). As a result, application of a positive polarity IEC pulse during testing may cause an oscillation, in which the voltage in the protection circuit goes negative, and conversely, a negative polarity pulse may cause a positive voltage in the protection circuit. Furthermore, key RF switch performance parameters can affect the response to an IEC pulse. In particular, techniques that improve a breakdown voltage in RF switches may negatively affect their tolerance to IEC type ESD events.

In practice, a high breakdown voltage and a low bipolar gain are characteristics of a high performance RF switch. Unfortunately, these device characteristics of high performance RF switches may increase their susceptibility to IEC ESD damage. One technique for improving an immunity of an RF switch to ESD is achieved by adding a resistive component to one side of each finger in a multi-finger RF switch circuit. In practice, the resistor is formed by adding a layer to provide a symmetric, silicide area block (SAB) against silicide (e.g., metal-silicon alloy) formation as well as self-aligned silicide (salicide). This resistor provides negative feedback to the circuit so that one finger in the multi-finger RF switch circuit does not begin conducting until the other fingers begin conducting. This asymmetry, however, may degrade linearity in an RF switch device. For example, if an ESD pulse can have positive or negative polarity with respect to the RF switch device and resistor orientation, the protection does not work equally for both polarities.

Various aspects of the present disclosure provide techniques for a symmetric radio frequency (RF) electrostatic discharge (ESD) dissipation switch. The process flow for semiconductor fabrication of the symmetric RF ESD dissipation switch may include front-end-of-line (FEOL) processes, middle-of-line (MOL) processes, and back-end-of-line (BEOL) processes. It will be understood that the term “layer” includes film and is not to be construed as indicating a vertical or horizontal thickness unless otherwise stated. As described herein, the term “substrate” may refer to a substrate of a diced wafer or may refer to a substrate of a wafer that is not diced. Similarly, the terms “chip” and “die” may be used interchangeably.

Some aspects of the present disclosure are directed to a symmetric RF ESD dissipation switch implemented in an RF integrated circuit. In some aspects of the present disclosure, the symmetric RF ESD dissipation switch is implemented by forming a switch field effect transistor (FET) having a resistor on both sides of each finger of the switch FET, which may be referred to as a ballast resistor. In some aspects of the present disclosure, an RF device includes a switch FET having a source region, a drain region, a body region, and a gate region. In these aspects of the present disclosure, the device includes the symmetric RF ESD dissipation switch that is formed by modifying the switch FET.

In some aspects of the present disclosure, the symmetric RF ESD dissipation switch is composed of a switch FET having a symmetric, silicide area block (SAB) on sidewall spacers and a first surface of a gate region opposite a gate oxide (Gox) of the gate region. As described, the symmetric SAB on the switch FET may be referred to as a ballast resistor. Because the switch FET includes the symmetric SAB on the switch FET, a second (2d) order linearity and a breakdown voltage of the switch FET are improved relative to an asymmetric SAB. Beneficially, the ballast resistor formed by the symmetric SAB on the switch FET provides negative feedback for both pulse polarities of an ESD pulse, which improves an overall ESD immunity of the device including the symmetric RF ESD dissipation switch.

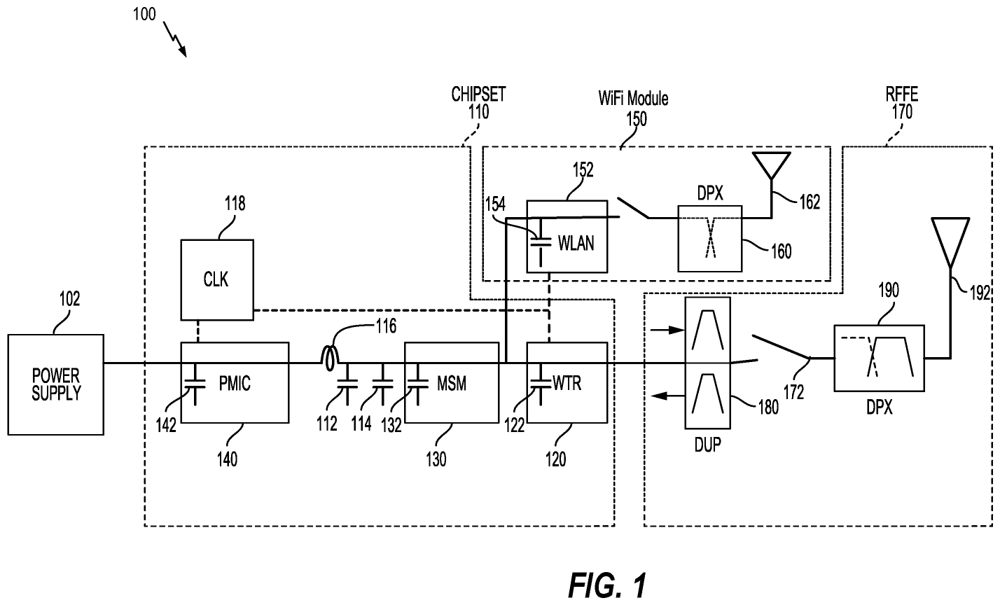

FIG. 1 is a schematic diagram of a wireless device 100 (e.g., a cellular phone or a smartphone) including a symmetric radio frequency (RF) electrostatic discharge (ESD) dissipation switch for improving the ESD performance of an RF switch device, according to aspects of the present disclosure. The wireless device 100 has a wireless local area network (WLAN) (e.g., Wi-Fi) module 150 and an RF front end (RFFE) 170 for a chipset 110. The Wi-Fi module 150 includes a first diplexer 160 communicably coupling an antenna 162 to a wireless local area network module (e.g., WLAN module 152). The RFFE 170 includes the second diplexer 190 communicably coupling an antenna 192 to the wireless transceiver 120 through a duplexer 180 (DUP). An RF switch 172 communicably couples the second diplexer 190 to the duplexer 180. The wireless transceiver 120 and the WLAN module 152 of the Wi-Fi module 150 are coupled to a modem (MSM, e.g., a baseband modem) 130 that is powered by a power supply 102 through a power management integrated circuit (PMIC) 140. The chipset 110 also includes capacitors 112 and 114, as well as an inductor(s) 116 to provide signal integrity. The PMIC 140, the modem 130, the wireless transceiver 120, and the WLAN module 152 each include capacitors (e.g., 142, 132, 122, and 154) and operate according to a clock 118. The geometry and arrangement of the various inductor and capacitor components in the chipset 110 may reduce the electromagnetic coupling between the components.

The wireless transceiver 120 of the wireless device generally includes a mobile RF transceiver to transmit and receive data for two-way communication. A mobile RF transceiver may include a transmit section for data transmission and a receive section for data reception. For data transmission, the transmit section may modulate an RF carrier signal with data to obtain a modulated RF signal, amplify the modulated RF signal using a power amplifier (PA) to obtain an amplified RF signal having the proper output power level, and transmit the amplified RF signal via the antenna 192 to a base station. For data reception, the receive section may obtain a received RF signal via the antenna and may amplify the received RF signal using a low noise amplifier (LNA) and process the received RF signal to recover data sent by the base station in a communication signal.

The wireless transceiver 120 may include one or more circuits for amplifying these communication signals. The amplifier circuits (e.g., LNA/PA) may include one or more amplifier stages that may have one or more driver stages and one or more amplifier output stages. Each of the amplifier stages includes one or more transistors configured in various ways to amplify the communication signals. Various options exist for fabricating the transistors that are configured to amplify the communication signals transmitted and received by the wireless transceiver 120.

The wireless transceiver 120 and the RFFE 170 may be implemented using semiconductor on insulator (SOI) technology for fabricating transistors of the wireless transceiver 120. Semiconductor on insulator (SOI) technology replaces conventional semiconductor (e.g., silicon) substrates with a layered semiconductor-insulator-semiconductor substrate for reducing parasitic device capacitance and improving performance in the RFFE 170.

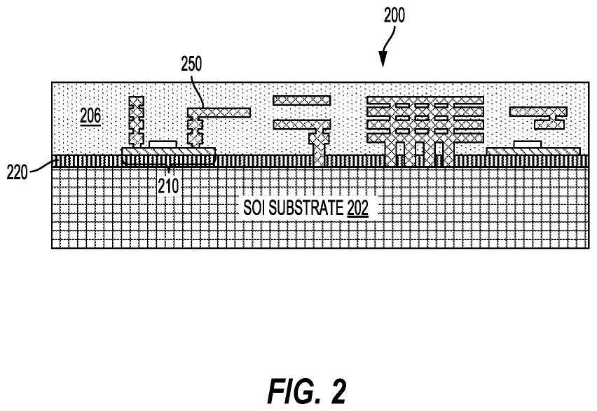

SOI-based devices differ from conventional, silicon-built devices because a silicon junction is above an electrical isolator, typically a buried oxide (BOX) layer, which defines the distance between the active device and the SOI substrate. That is, device performance is degraded by increasing a proximity of the active device and the SOI substrate in future process nodes. The active devices on an SOI layer may include high performance transistors. For example, high performance RF switch technologies are currently manufactured using SOI substrates. The RFFE 170 may rely on these high performance RF switch technologies for successful operation by using active devices fabricated using SOI technology, which is shown in FIG. 2.

FIG. 2 shows a cross-sectional view of a radio frequency (RF) integrated circuit (RFIC) 200. As shown in FIG. 2, an RF silicon on insulator (SOI) device includes an active device 210 on a buried oxide (BOX) layer 220 supported by an SOI substrate 202 (e.g., a silicon wafer). The RF SOI device may be fabricated as a complementary metal oxide semiconductor (CMOS) transistor using a CMOS process. The RF SOI device also includes interconnects 250 coupled to the active device 210 within a first dielectric layer 206. In this configuration, a parasitic capacitance of the RF SOI device is proportional to a thickness of the BOX layer 220, which determines the distance between the active device 210 and the SOI substrate 202.

The active device 210 on the BOX layer 220 may be a CMOS transistor. For example, high performance CMOS RF switch technologies are currently manufactured using SOI substrates. The RFFE 170 (FIG. 1) may rely on these high performance CMOS RF technologies for successful operation. A process for fabricating the RFFE 170, therefore, involves integration of an SOI wafer to support these high performance CMOS RF technologies. Furthermore, support for future RF performance enhancements involves increased device isolation while reducing RF loss. The RFIC 200 may be used to implement the RFFE 170 in FIG. 1. For example, the active device 210 may be a switch field effect transistor (FET) of the RF switch 172 of the RFFE 170.

The configuration of the RFIC 200 reduces parasitic device capacitance and improves performance by using an SOI wafer for implementing the RFFE 170. A process for fabricating an RFFE 170, therefore, involves the costly integration of an SOI wafer for supporting these high performance RF switch technologies (e.g., RF switch 172). In practice, a high performance RF switch manufactured using an SOI substrate is generally characterized by a high breakdown voltage and a low bipolar gain. Unfortunately, these RF switch performance parameters can affect the response of the RF switch 172 to an electrostatic discharge (ESD) pulse. In particular, techniques that improve a breakdown voltage in the RF switch 172 negatively affect a tolerance of the RF switch 172 to ESD events.

For example, IEC 61000-4-2 is an electrostatic discharge (ESD) immunity standard from the International Electrotechnical Commission (IEC). As used in the mobile phone industry, the IEC 61000-4-2 standard is designed to test immunity from humans touching an antenna and damaging the RFFE 170, when implemented in a mobile phone. The IEC 61000-4-2 standard differs from the human-body model (HBM) and the charged-device (CDC) model because the IEC 61000-4-2 standard involves higher frequency components and lower series resistance. In particular, testing according to the IEC 61000-4-2 standard is performed with both positive and negative polarity pulses applied to the RF ports of the RFFE 170 implemented in a mobile phone.

Techniques for reducing a susceptibility of the RF switch 172 to electrostatic discharge (ESD) damage are desired. In practice, a protection circuit composed of a shunt inductor is implemented in mobile phones for supporting testing according to the IEC 61000-4-2 standard. In operation, a small inductance causes some RF signal loss, which is detrimental for radio sensitivity. As a result, customers specify a large inductance in the RFFE 170 implemented in a mobile device. Unfortunately, a large inductance can lead to resonance in the RFFE 170. As a result, application of a positive polarity IEC pulse during testing may cause an oscillation, in which the voltage in the protection circuit goes negative and, conversely, a negative polarity pulse may cause a positive voltage in the protection circuit. Furthermore, key RF switch performance parameters can affect the response to an IEC pulse. In particular, techniques that improve a breakdown voltage in RF switches negatively affect tolerance of the RF switch 172 to IEC type ESD events.

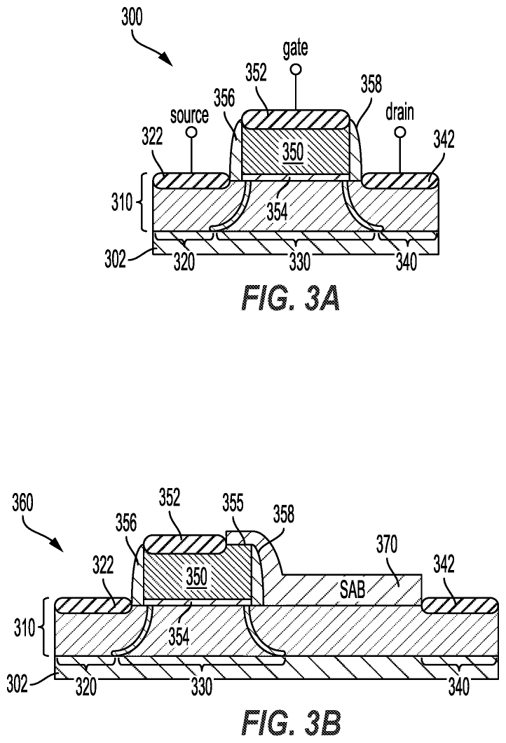

FIG. 3A is a schematic diagram illustrating a switch field effect transistor (FET) 300. In this example, the switch FET 300 includes a buried oxide (BOX) layer 302 on which a semiconductor on insulator (SOI) layer 310 is formed. In this implementation, the SOI layer 310 includes a source region 320, a body region 330, a drain region 340, and a gate region 350. The source region 320 includes a source contact 322, and the drain region 340 includes a drain contact 342. In this configuration, the gate region 350 includes a gate contact 352 on a surface of the gate region 350 opposite a gate oxide (Gox) layer 354 on the SOI layer 310. The gate region 350 also includes a first sidewall spacer 356 and a second sidewall spacer 358. In practice, a high breakdown voltage and a low bipolar gain are characteristics of a high performance RF switch including the switch FET 300. Unfortunately, these device characteristics of high performance RF switches increase their susceptibility to IEC ESD damage.

FIG. 3B is a schematic diagram illustrating a switch field effect transistor (FET) 360 having an asymmetric, silicide area block (SAB) 370. One technique for improving an immunity of the switch FET 360 to electrostatic discharge (ESD) events is achieved by adding a resistive component to one side of each finger in the switch FET 360. For example, as shown in FIG. 3B, the switch FET 360 includes the asymmetric SAB 370 on a surface of the SOI layer 310, on the second sidewall spacer 358, and on a portion of a first surface 355 of the gate region 350. In practice, the resistor is formed by depositing an oxide layer surface of the SOI layer 310, on the second sidewall spacer 358, and on a portion of the first surface 355 of the gate region 350 to form the asymmetric SAB 370 against the silicide formation. This resistor provided by the asymmetric SAB 370 provides negative feedback to the circuit so that one finger in a multi-finger switch circuit does not begin conducting until the other fingers begin conducting. This asymmetry, however, may degrade linearity in the switch FET 360. For example, if an ESD pulse can have positive or negative polarity with respect to the switch FET 360 and the orientation of the asymmetric SAB 370, any protection from the switch FET 360 does not work equally for both polarities.

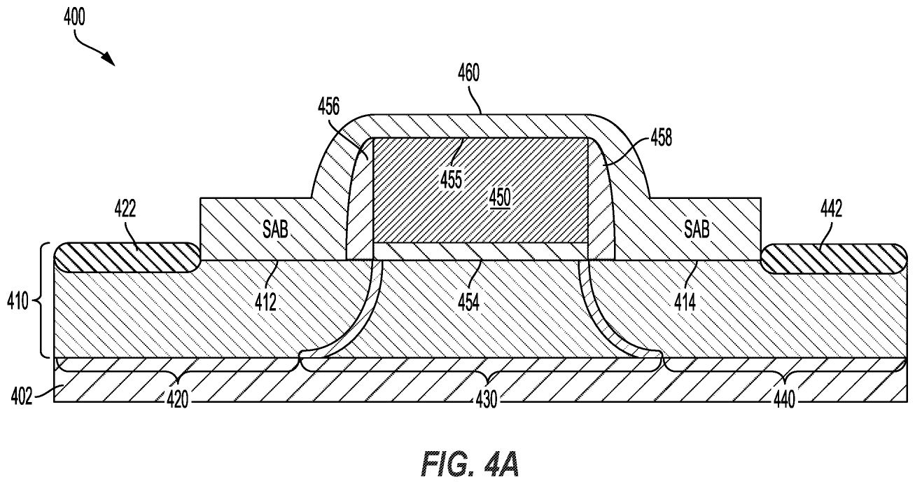

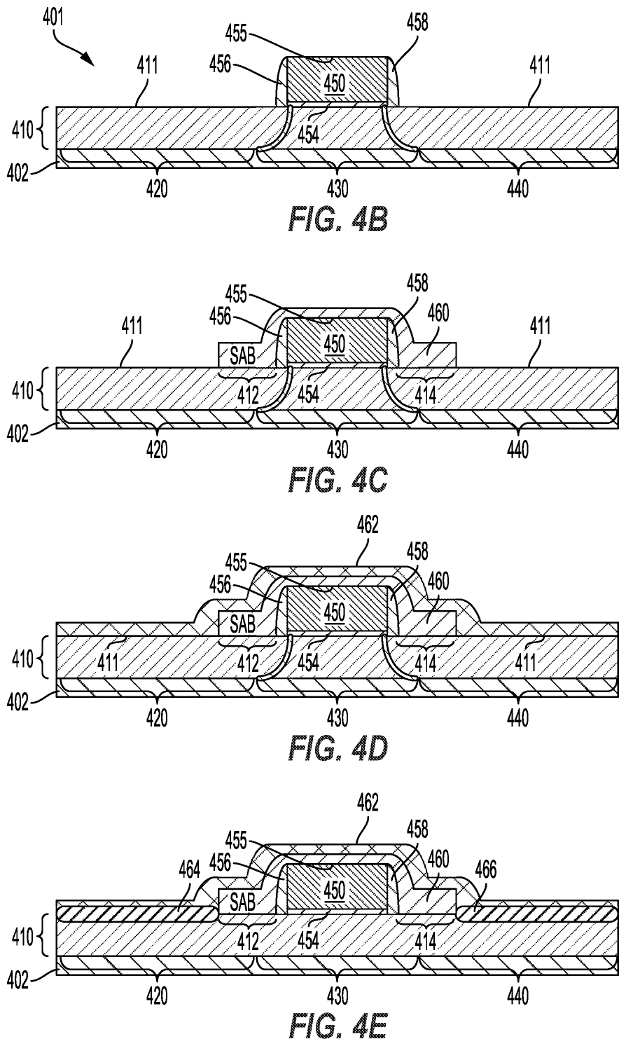

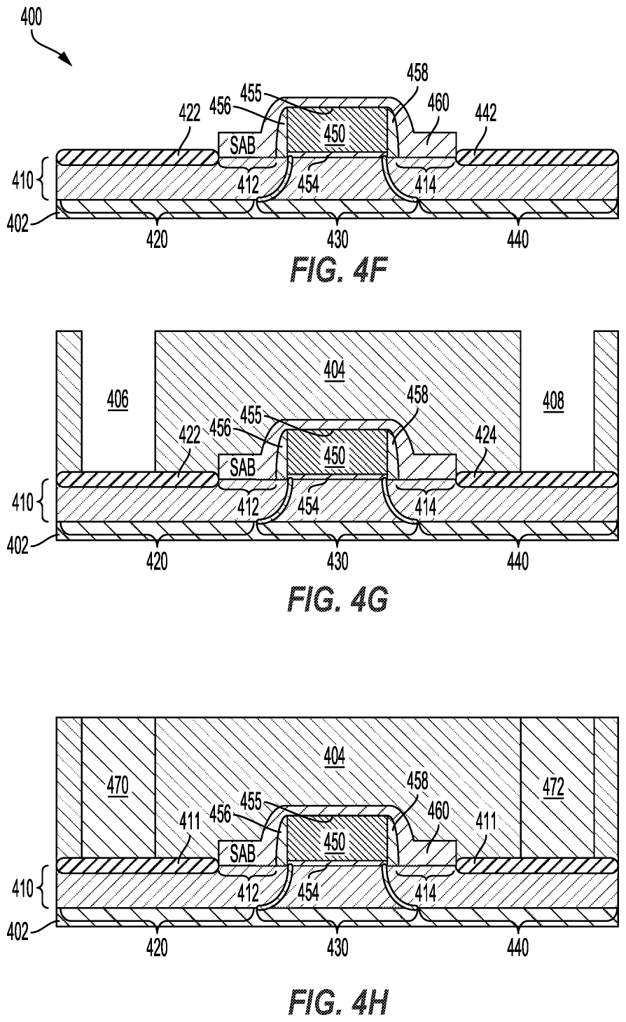

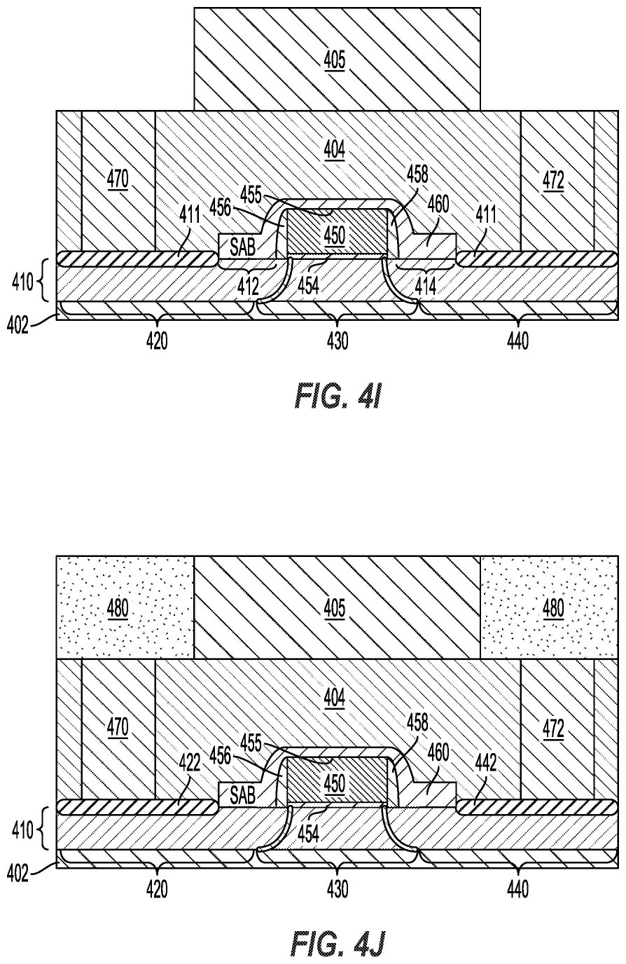

FIGS. 4A-4J are schematic drawings illustrating a symmetric radio frequency (RF) electrostatic discharge (ESD) dissipation switch and a process for forming the symmetric RF ESD dissipation switch, according to aspects of the present disclosure.

As shown in FIG. 4A, a symmetric RF ESD dissipation switch 400, is composed of a switch field effect transistor (FET), including a BOX layer 402 on which an active layer 410 (e.g., a semiconductor on insulator (SOI)) is formed, which may be collectively referred to as a substrate. In this implementation, the active layer 410 includes a source region 420, a body region 430, a drain region 440, and a gate 450. The source region 420 includes a source silicide region 422, and the drain region 440 includes a drain silicide region 442. In this configuration, the gate 450 includes a gate oxide (Gox) layer 454 and a first surface 455 opposite the Gox layer 454. The gate 450 also includes a first sidewall spacer 456 and a second sidewall spacer 458 opposite the first sidewall spacer 456.

In some aspects of the present disclosure, a susceptibility of the switch FET to ESD damage is reduced by forming a symmetric, silicide area block (SAB) 460 on the gate 450. In this example, the symmetric SAB 460 is formed on a first surface region 412 and a second surface region 414 of the active layer 410 as well as the first sidewall spacer 456, the first surface 455, and the second sidewall spacer 458 of the gate 450. Subsequent to forming the symmetric SAB 460, contacts are formed to the source silicide region 422 and the drain silicide region 442, as further illustrated in FIGS. 4B-4J.

FIG. 4B is a schematic drawings illustrating a process for forming the symmetric RF ESD dissipation switch of FIG. 4A, according to aspects of the present disclosure. As shown in FIG. 4B, a switch FET 401 of the symmetric RF ESD dissipation switch 400 of FIG. 4A is formed. In this example, the first surface region 412 and the second surface region of the active layer 410 of the switch FET 401 are exposed, prior to formation of the symmetric SAB 460.

FIG. 4C is a schematic drawings further illustrating the process for forming the symmetric RF ESD dissipation switch of FIG. 4A, according to aspects of the present disclosure. As shown in FIG. 4C, an oxide layer (e.g., silicon oxide or silicon nitride) is deposited on the switch FET 401 as well as a surface 411 of the active layer 410 of the switch FET 401. Subsequently, the oxide layer is patterned to block formation of silicide film. The remaining portion of the oxide layer forms the symmetric SAB 460 on the first surface region 412 and the second surface region 414 of the active layer 410 as well as the first sidewall spacer 456, the first surface 455, and the second sidewall spacer 458 of the gate 450.

FIG. 4D is a schematic drawings further illustrating the process for forming the symmetric RF ESD dissipation switch of FIG. 4A, according to aspects of the present disclosure. As shown in FIG. 4D, a metal layer 462 is uniformly deposited on the symmetric SAB 460 and the surface 411 of the active layer 410. In this example, the metal layer 462 enables formation of a silicide layer, for example, as shown in FIG. 4E.

FIG. 4E is a schematic drawings further illustrating the process for forming the symmetric RF ESD dissipation switch of FIG. 4A, according to aspects of the present disclosure. As shown in FIG. 4E, a thermal process is applied to the metal layer 462 on the symmetric SAB 460 and the surface 411 of the active layer 410 to form a first silicide alloy 464 and a second silicide alloy 466. In this example, the symmetric SAB 460 prevents formation of a silicide layer on the first surface 455 of the gate 450 and on the first surface region 412 and the second surface region 414 of the active layer 410 by preventing diffusion of the metal layer 462 in these unexposed surfaces and regions.

FIG. 4F is a schematic drawings further illustrating the process for forming the symmetric RF ESD dissipation switch of FIG. 4A, according to aspects of the present disclosure. As shown in FIG. 4F, a chemical etch process is applied to the metal layer 462 on the symmetric SAB 460 and on first silicide alloy 464 and the second silicide alloy 466. This etch process exposes the symmetric SAB 460 as well as the first silicide alloy 464 and the second silicide alloy 466 to form the source silicide region 422 and the drain silicide region 442 and complete the symmetric RF ESD dissipation switch of FIG. 4A.

FIG. 4G is a schematic drawings further illustrating the process for forming the symmetric RF ESD dissipation switch of FIG. 4F, according to aspects of the present disclosure. As shown in FIG. 4G, a contact oxide 404 is deposited on the symmetric SAB 460 and on the source silicide region 422 and the drain silicide region 442. Once the contact oxide 404 is formed an etched process is applied to the contact oxide to form a first opening 406 exposing the source silicide region 422, and a second opening 408 exposing the drain silicide region 424.

FIG. 4H is a schematic drawings further illustrating the process for forming the symmetric RF ESD dissipation switch of FIG. 4G, according to aspects of the present disclosure. As shown in FIG. 4H, a conductive film (e.g., a tungsten film) is deposited across the contact oxide 404 and polished back to fill the first opening 406 and the second opening 408. This process forms a source contact 470 to the source silicide region 422 and a drain contact 472 to the drain silicide region 442.

FIG. 4I is a schematic drawings further illustrating the process for forming the symmetric RF ESD dissipation switch of FIG. 4H, according to aspects of the present disclosure. As shown in FIG. 4I, a first interlayer dielectric (ILD) layer 405 is deposited on the contact oxide 404 as well as exposed portions of the source contact 470 and the drain contact 472. The first ILD layer 405 is etched to expose a surface of the source contact 470 and the drain contact 472 as well as a surface of the contact oxide 404.

FIG. 4J is a schematic drawings further illustrating the process for forming the symmetric RF ESD dissipation switch of FIG. 4I, according to aspects of the present disclosure. As shown in FIG. 4J, a first metallization layer 480 (e.g., a back-end-of-line (BEOL) M1 layer) is deposited on the exposed surface of the source contact 470 and the drain contact 472, the surface of the contact oxide 404, and the first ILD layer 405. The first metallization layer 480 is subsequently polished to fill desired contact areas.

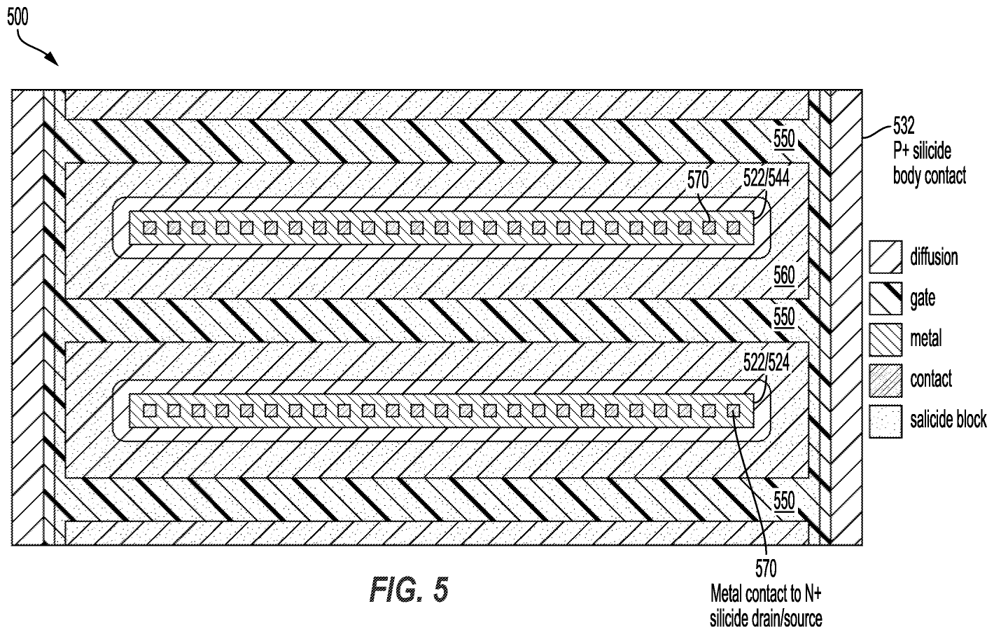

Some aspects of the present disclosure are directed to the symmetric RF ESD dissipation switch 400 implemented in an RF integrated circuit. In some aspects of the present disclosure, the symmetric RF ESD dissipation switch 400 is implemented by forming the symmetric SAB 460 to provide a resistor on both sides of each finger of the switch FET, for example, as shown in FIG. 5. The resistor provided by the symmetric SAB 460 may be referred to as a ballast resistor. Because the symmetric RF ESD dissipation switch 400 includes the symmetric SAB 460, a second (2^{nd}) order linearity and a breakdown voltage are improved relative to the asymmetric SAB 370 shown in FIG. 3B. Beneficially, the ballast resistor provided by the symmetric SAB 460 provides negative feedback for both pulse polarities of an ESD pulse, which improves an overall ESD immunity of an RFIC including the symmetric RF ESD dissipation switch 400.

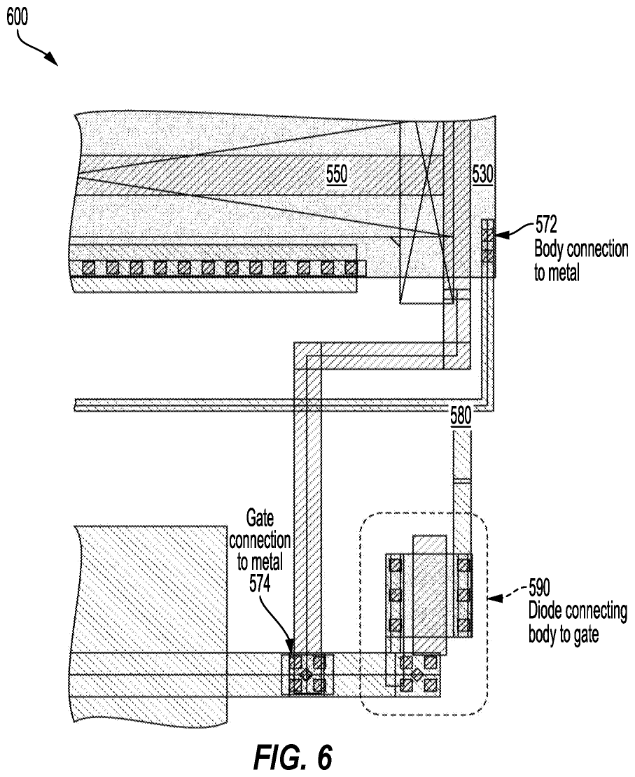

FIG. 5 is a schematic diagram illustrating a layout view of a multi-finger symmetric radio frequency (RF) electrostatic discharge (ESD) dissipation switch, according to aspects of the present disclosure. This example may represent a top view of the symmetric RF ESD dissipation switch 400 of FIG. 4A, in a multi-finger configuration. As a result, the multi-finger, ESD dissipation switch 500 is shown in FIG. 5 using similar reference numbers. In some aspects of the present disclosure, the ESD dissipation switch 500 includes multiple gates 550 covered by a symmetric SAB 560 as well as source/drain silicide regions 522/544 and diffusion regions (e.g., 512/514). In addition, source/drain contacts 570 (e.g., a middle-of-line (MOL) interconnect layer) to the source/drain silicide regions 522/544, as well as a body silicide region 532 (e.g., a P+ body silicide region), are shown. A connection between the body silicide region 532 and a gate silicide region is further illustrated in FIG. 6.

FIG. 6 is a schematic diagram 600 further illustrating the connection between the body silicide region 532 and a gate silicide region of the ESD dissipation switch 500 of FIG. 5, in accordance with aspects of the present disclosure. In this configuration, a body contact 572 between the body silicide region 532 and a first metallization layer 580 (e.g., M1) is shown. In addition, connection of a gate contact 574 to the first metallization layer 580 is also shown, in which the body contact 572 is on the body silicide region 532 and the gate contact 554 is on a gate silicide region. In this example, a diode 590 provides a connection between the gate contact 574 and the body contact 572.

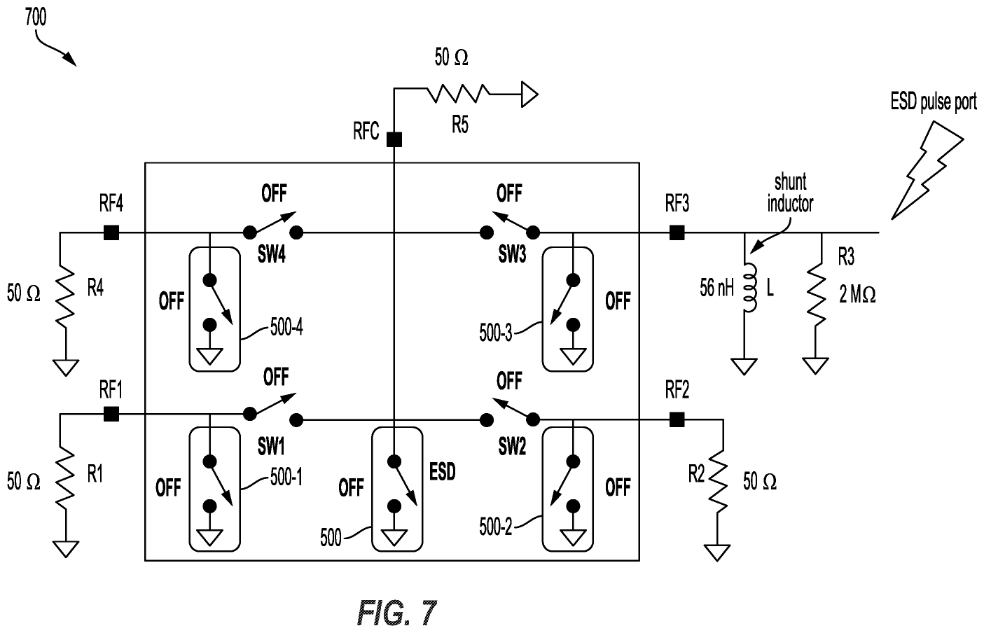

FIG. 7 is a schematic diagram illustrating a radio frequency (RF) device 700, including RF switches and symmetric RF electrostatic discharge (ESD) dissipation switches, in accordance with aspects of the present disclosure. As shown in FIG. 7, the RF device 700 includes a first radio frequency (RF) switch (SW1) coupled in series to a first RF port (RF1) and coupled in parallel to an RF common (RFC) port. In some aspects of the present disclosure, the RF device 700 also includes an electrostatic discharge (ESD) dissipation switch 500 coupled to the RFC port. For example, as shown in FIG. 4A, the ESD dissipation switch 500 is composed of the symmetric RF ESD dissipation switch 400 including the source region 420, the drain region 440, the body region 430, and the gate 450. In this example, the symmetric RF ESD dissipation switch 400 includes the symmetric SAB 460 on the first surface region 412 and a second surface region 414 of the active layer 410, as well as the first sidewall spacer 456, the first surface 455, and the second sidewall spacer 458 of the gate 450.

Referring again to FIG. 7, the RF device 700 also includes a first resistor R1 (e.g., a 50 Ohm resistor) coupled to the RF1 port. In addition, a first shunt ESD dissipation switch 500-1 is coupled in a shunt connection between the RF1 port and the first RF switch SW1. In some aspects of the present disclosure, the RF device 700 further includes a second RF switch SW2 coupled in series to the first RF switch SW1 and a second RF port (RF2). The second RF switch SW2 is also coupled in parallel with the RFC port. In this example, the RF device 700 further includes a second shunt ESD dissipation switch 500-2 coupled in a shunt connection between the RF2 port and the second RF switch SW2. In addition, a second resistor R2 (e.g., a 50 Ohm resistor) is coupled to the RF2 port.

As shown in FIG. 7, the RF device 700 further includes a third RF switch SW3 coupled in series to a third RF port (RF3) and coupled in parallel to the RFC port. In addition, the RF device 700 further includes a third shunt ESD dissipation switch 500-3 coupled in a shunt connection between the RF3 port and the third RF switch SW3. In some aspects of the present disclosure, the RF device 700 further includes a fourth RF switch SW4 coupled in series to a fourth RF switch SW4, and a fourth RF port (RF4). The fourth RF switch SW4 is also coupled in parallel with the RFC port. In this example, the RF device 700 further includes a fourth shunt ESD dissipation switch 500-4 coupled in a shunt connection between the RF4 port and the fourth RF switch SW4. In addition, a fourth resistor R4 (e.g., a 50 Ohm resistor) is coupled to the RF4 port, and a fifth resistor R5 (e.g., a 50 Ohm resistor) is coupled to the RFC port.

In some aspects of the present disclosure, a shunt inductor L (e.g., 56 nanohenries (nH)) is coupled to the RF3 port. In addition, a third resistor R3 (e.g., 2 megaohms) is coupled to the RF3 port. In this example, the third RF3 port is configured as an ESD pulse port. In response to an ESD pulse, the ESD dissipation switch 500 and the four shunt ESD dissipation switches (e.g., 500-1, 500-2, 500-3, 500-4) may operate to protect the RF device 700. In particular, the ballast resistor provided by the symmetric SAB 560 of the ESD dissipation switch 500 and the shunt ESD dissipation switches provides a negative feedback for both positive and negative polarity of the ESD pulse, which improves an overall ESD immunity of the RF device 700.

Beneficially, the symmetric SABs of the switch FETs provide improved IEC immunity over non-symmetric SABs and asymmetric SAB devices. In addition, a linearity of the symmetric SAB switch FETs is the same as the standard RF switch in the same technology area. Furthermore, a breakdown voltage of the symmetric SAB switch FETs is approximately 0.1 V (or 3%) lower than the standard RF switch, which is negligible for RF applications, according to aspects of the present disclosure. The area occupied by the structures of the symmetric SAB switch FETs may be 0.038 mm² in some implementations. It is noted that the values (e.g., 56 nH, 50 Ohms, etc.) shown in FIG. 7 are merely non-limiting examples. Other sized components are also contemplated.

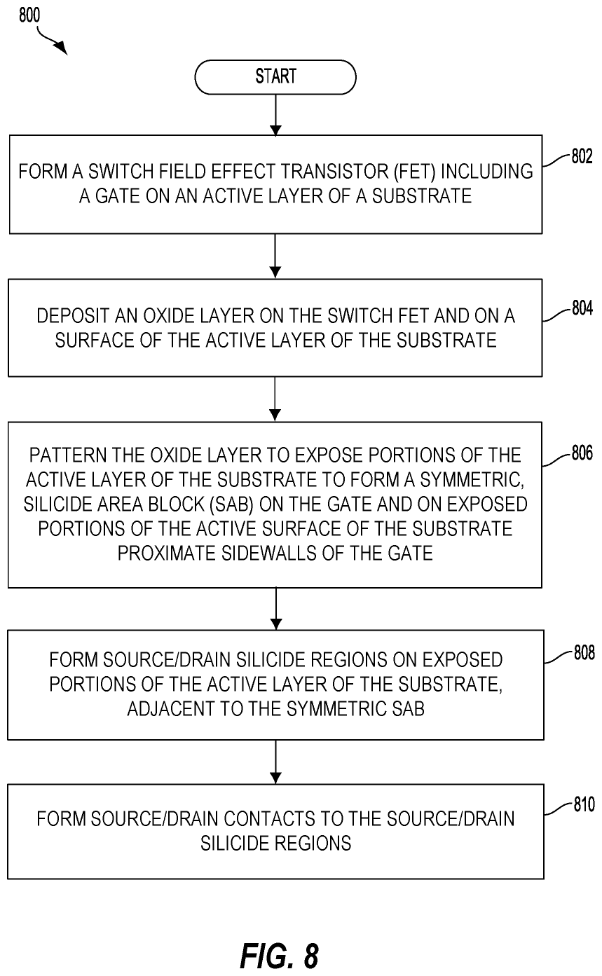

FIG. 8 is a process flow diagram illustrating a method 800 for constructing a radio frequency (RF) device having a symmetric RF electrostatic discharge (ESD) dissipation switch, according to aspects of the present disclosure. A method 800 begins in block 802, in which a switch field effect transistor (FET) is formed, including a gate on an active layer of a substrate. For example, as shown in FIG. 4B, a switch FET 401 of the symmetric RF ESD dissipation switch 400 of FIG. 4A is formed. In this example, the first surface region 412 and the second surface region of the active layer 410 of the switch FET 401 are exposed, prior to formation of the symmetric SAB 460, as shown in FIG. 4C.

As further shown in FIG. 8, in block 804, an oxide layer is deposited on the switch FET and on a surface of the active layer of the substrate. For example, as shown in FIG. 4C, an oxide layer (e.g., silicon oxide or silicon nitride) is deposited on the switch FET 401 as well as a surface 411 of the active layer 410 of the switch FET 401. In this configuration, the gate 450 includes a gate oxide (Gox) layer 454 and a first surface 455 opposite the Gox layer 454. The gate 450 also includes a first sidewall spacer 456 and a second sidewall spacer 458 opposite the first sidewall spacer 456.

At block 806, the oxide layer is patterned to expose portions of the active layer of the substrate to form a symmetric, silicide area block (SAB) on the gate and on exposed portions of the active surface of the substrate proximate sidewalls of the gate. For example, as shown in FIG. 4C, the oxide layer is patterned to enable formation of silicide film on exposed area of the switch FET 401. The remaining portion of the oxide layer forms the symmetric SAB 460 on the first surface region 412 and the second surface region 414 of the active layer 410 as well as the first sidewall spacer 456, the first surface 455, and the second sidewall spacer 458 of the gate 450. Beneficially, a susceptibility of the switch FET to ESD damage is reduced by forming the symmetric SAB 460 on the gate 450.

At block 808, source/drain silicide regions are formed on exposed portions of the active layer of the substrate, adjacent to the symmetric SAB. For example, as shown in FIG. 4D-4F, a metal layer 462 is uniformly deposited on the symmetric SAB 460 and the surface 411 of the active layer 410. In this example, the metal layer 462 enables formation of a silicide layer. For example, as shown in FIG. 4E. a thermal process is applied to the metal layer 462 on the symmetric SAB 460 and the surface 411 of the active layer 410 to form a first silicide alloy 464 and a second silicide alloy 466. In this example, the symmetric SAB 460 prevents formation of a silicide layer on the first surface 455 of the gate 450 and on the first surface region 412 and the second surface region 414 of the active layer 410 by preventing diffusion of the metal layer 462 in these unexposed surfaces and regions. As shown in FIG. 4F, a chemical etch process is applied to the metal layer 462 on the symmetric SAB 460 and on first silicide alloy 464 and the second silicide alloy 466. This etch process exposes the symmetric SAB 460 as well as the first silicide alloy 464 and the second silicide alloy 466 to form the source silicide region 422 and the drain silicide region 442 and complete the symmetric RF ESD dissipation switch of FIG. 4A.

At block 810, source/drain contacts are formed to the source/drain silicide regions. For example, as shown in FIGS. 4G, a contact oxide 404 is deposited on the symmetric SAB 460 and on the source silicide region 422 and the drain silicide region 442. Once the contact oxide 404 is formed.an etched process is applied to the contact oxide to form a first opening 406 exposing the source silicide region 422, and a second opening 408 exposing the drain silicide region 424. As shown in FIG. 4H, a conductive film (e.g., a tungsten film) is deposited across the contact oxide 404 and polished back to fill the first opening 406 and the second opening 408. This process forms a source contact 470 to the source silicide region 422 and a drain contact 472 to the drain silicide region 442.

Some aspects of the present disclosure are directed to a symmetric RF electrostatic discharge (ESD) dissipation switch implemented in an RF integrated circuit. In some aspects of the present disclosure, the symmetric RF ESD dissipation switch is implemented by forming a switch field effect transistor (FET) having a resistor on both sides of each finger of the switch FET, which may be referred to as a ballast resistor. In some aspects of the present disclosure, an RF device includes a switch field effect transistor (FET) having a source region, a drain region, a body region, and a gate region. In these aspects of the present disclosure, the device includes the symmetric RF ESD dissipation switch and is formed by modifying the switch FET. For example, the symmetric RF ESD dissipation switch is composed of a switch FET having a symmetric, symmetric, silicide area block (SAB) on sidewall spacers and a first surface of a gate region opposite a gate oxide (Gox) of the gate region of the switch FET.

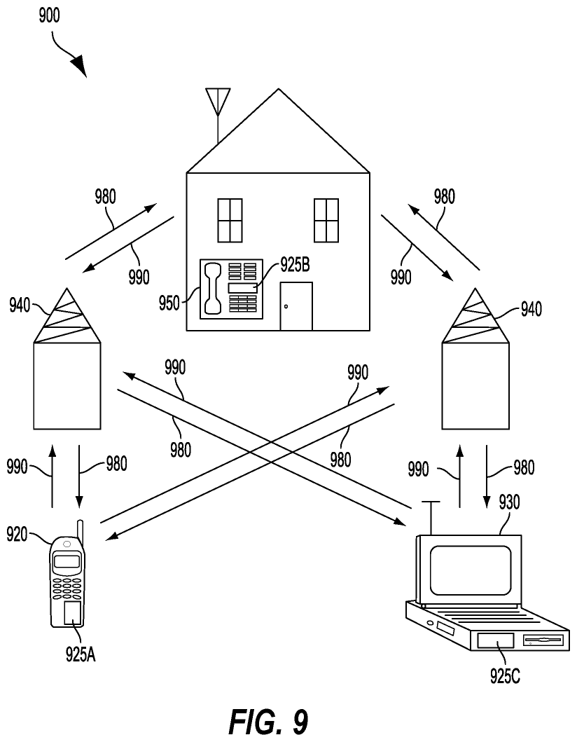

FIG. 9 is a block diagram showing an exemplary wireless communications system 900 in which an aspect of the present disclosure may be advantageously employed. For purposes of illustration, FIG. 9 shows three remote units 920, 930, and 950 and two base stations 940. It will be recognized that wireless communications systems may have many more remote units and base stations. Remote units 920, 930, and 950 include IC devices 925A, 925C, and 925B that include the disclosed symmetric SAB switch field effect transistors (FETs). It will be recognized that other devices may also include the disclosed symmetric SAB switch field effect transistors (FETs), such as the base stations, switching devices, and network equipment. FIG. 9 shows forward link signals 980 from the base station 940 to the remote units 920, 930, and 950 and reverse link signals 990 from the remote units 920, 930, and 950 to base stations 940.

In FIG. 9, remote unit 920 is shown as a mobile telephone, remote unit 930 is shown as a portable computer, and remote unit 950 is shown as a fixed location remote unit in a wireless local loop system. For example, a remote units may be a mobile phone, a hand-held personal communication systems (PCS) unit, a portable data unit such as a personal digital assistant (PDA), a GPS enabled device, a navigation device, a set top box, a music player, a video player, an entertainment unit, a fixed location data unit such as a meter reading equipment, or other communications device that stores or retrieve data or computer instructions, or combinations thereof. Although FIG. 9 illustrates remote units, according to the aspects of the present disclosure, the present disclosure is not limited to these exemplary illustrated units. Aspects of the present disclosure may be suitably employed in many devices, which include the disclosed symmetric SAB, switch FETs.

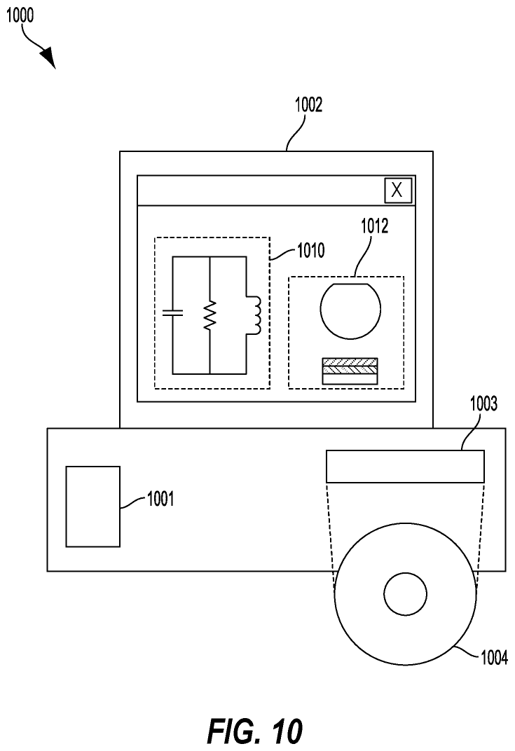

FIG. 10 is a block diagram illustrating a design workstation used for circuit, layout, and logic design of a semiconductor component, such as the symmetric SAB switch FETs disclosed above. A design workstation 1000 includes a hard disk 1001 containing operating system software, support files, and design software such as Cadence or OrCAD. The design workstation 1000 also includes a display 1002 to facilitate a circuit design 1010 or an RFIC 1012. A storage medium 1004 is provided for tangibly storing the circuit design 1010 or the RFIC 1012. The circuit design 1010 or the RFIC 1012 may be stored on the storage medium 1004 in a file format such as GDSII or GERBER. The storage medium 1004 may be a CD-ROM, DVD, hard disk, flash memory, or other appropriate device. Furthermore, the design workstation 1000 includes a drive apparatus 1003 for accepting input from or writing output to the storage medium 1004.

Data recorded on the storage medium 1004 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1004 facilitates the design of the circuit design 1010 or the RFIC 1012 by decreasing the number of processes for designing semiconductor wafers.

Implementation examples are described in the following numbered clauses:

1. A radio frequency device, comprising:
a first radio frequency (RF) switch coupled in series to a first RF port and coupled in parallel to an RF common (RFC) port; and an electrostatic discharge (ESD) dissipation switch coupled to the RF common port and comprising a switch field effect transistor (FET) including a gate on an active layer of a substrate, and a symmetric silicide area block (SAB) on a first sidewall spacer and a second sidewall spacer, opposite the first sidewall spacer, and on a gate surface of the gate, opposite the active layer of the substrate.

2. The RF device of clause 1, in which the symmetric SAB is on a first surface region of the active layer of the substrate, proximate the first sidewall spacer, and on a second surface region of the active layer of the substrate, proximate the second sidewall spacer.

3. The RF device of any of clauses 1 or 2, in which the switch FET comprises:
a source region in the active layer of the substrate; and
a source silicide region coupled to the source region, in which the source silicide region is separated from the first sidewall spacer by a portion of the symmetric SAB on a surface of the active layer of the substrate.

4. The RF device of any of clauses 1-3, in which the switch FET comprises:
a drain region in the active layer of the substrate; and
a drain silicide region coupled to the drain region, in which the drain silicide region is separated from the second sidewall spacer by a portion of the symmetric SAB on a surface of the active layer of the substrate.

5. The RF device of any of clauses 1-4, further comprising a first shunt ESD dissipation switch coupled in a shunt connection between the first RF port and the first RF switch.

6. The RF device of any of clauses 1-5, further comprising a second RF switch coupled in series to the first RF switch and a second RF port, and coupled in parallel to the RFC port.

7. The RF device of clause 6, further comprising a second shunt ESD dissipation switch coupled in a shunt connection between the second RF port and the second RF switch.

8. The RF device of any of clauses 6 or 7, in which the second RF port comprises an ESD pulse port.

9. The RF device of any of clauses 1-8, integrated in an RF front end (RFFE) module.

10. The RF device of clause 9, in which the RFFE module incorporated in at least one of a music player, a video player, an entertainment unit, a navigation device, a communications device, a personal digital assistant (PDA), a fixed location data unit, a mobile phone, and a portable computer.

11. A method for constructing a radio frequency (RF) device having a symmetric RF electrostatic discharge (ESD) dissipation switch, comprising:
forming a switch field effect transistor (FET) including a gate on an active layer of a substrate;
depositing an oxide layer on the switch FET and on a surface of the active layer of the substrate;
patterning the oxide layer to expose portions of the active layer of the substrate to form a symmetric silicide area block (SAB) on the gate and on exposed portions of the active layer of the substrate proximate sidewalls of the gate;
forming source/drain silicide regions on exposed portions of the active layer of the substrate, adjacent to the symmetric SAB; and
forming source/drain contacts to the source/drain silicide regions.

12. The method of clause 11, in which the symmetric SAB is on a first surface region of the active layer of the substrate, proximate a first sidewall spacer, and on a second surface region of the active layer of the substrate, proximate a second sidewall spacer.

13. The method of any of clauses 11 or 12, in which forming the switch FET comprises:
forming a source region in the active layer of the substrate, in which the source silicide region is coupled to the source region and separated from a first sidewall spacer of the gate by a portion of the symmetric SAB on a surface of the active layer of the substrate.

14. The method of any of clauses 11-13, in which forming the switch FET comprises:
forming a drain region in the active layer of the substrate, in which the drain silicide region is coupled to the drain region and separated from a second sidewall spacer of the gate by a portion of the symmetric SAB on a surface of the active layer of the substrate.

15. The method of any of clauses 11-14, further comprising:
coupling a first radio frequency (RF) switch in series to a first RF port and in parallel to an RF common (RFC) port; and
coupling the symmetric RF ESD dissipation switch to the RFC port.

16. The method of clause 15, further comprising coupling a first shunt ESD dissipation switch in a shunt connection between the first RF port and the first RF switch.

17. The method of any of clauses 15 or 16, further comprising coupling a second RF switch in series to the first RF switch and a second RF port, and in parallel to the RFC port.

18. The method of clause 17, further comprising coupling a second shunt ESD dissipation switch in a shunt connection between the second RF port and the second RF switch, in which the second RF port comprises an ESD pulse port.

19. The method of any of clauses 11-18, further comprising integrating the RF device in an RF front end (RFFE) module.

20. The method of clause 19, further comprising incorporating the RFFE module in at least one of a music player, a video player, an entertainment unit, a navigation device, a communications device, a personal digital assistant (PDA), a fixed location data unit, a mobile phone, and a portable computer.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made herein without departing from the technology of the present disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, and composition of matter, means, methods, and steps described in the specification. As one of ordinary skill in the art will readily appreciate from the present disclosure, processes, machines, manufacture, compositions of matter, means, methods, or steps, presently existing or later to be developed that perform substantially the same function or achieve substantially the same result as the corresponding configurations described herein may be utilized, according to the present disclosure. Accordingly, the appended claims are intended to include within their scope such processes, machines, manufacture, compositions of matter, means, methods, or steps.

What is claimed is:

1. A radio frequency device, comprising:
a first radio frequency (RF) switch coupled in series to a first RF port and coupled in parallel to an RF common (RFC) port; and
an electrostatic discharge (ESD) dissipation switch coupled to the RF common port and comprising a switch field effect transistor (FET) including a gate on an active layer of a substrate, and a symmetric silicide area block (SAB) on a first sidewall spacer and a second sidewall spacer, opposite the first sidewall spacer, and on a gate surface of the gate, opposite the active layer of the substrate.

2. The RF device of claim 1, in which the symmetric SAB is on a first surface region of the active layer of the substrate, proximate the first sidewall spacer, and on a second surface region of the active layer of the substrate, proximate the second sidewall spacer.

3. The RF device of claim 1, in which the switch FET comprises:
a source region in the active layer of the substrate; and
a source silicide region coupled to the source region, in which the source silicide region is separated from the first sidewall spacer by a portion of the symmetric SAB on a surface of the active layer of the substrate.

4. The RF device of claim 1, in which the switch FET comprises:
a drain region in the active layer of the substrate; and
a drain silicide region coupled to the drain region, in which the drain silicide region is separated from the second sidewall spacer by a portion of the symmetric SAB on a surface of the active layer of the substrate.

5. The RF device of claim 1, further comprising a first shunt ESD dissipation switch coupled in a shunt connection between the first RF port and the first RF switch.

6. The RF device of claim 1, further comprising a second RF switch coupled in series to the first RF switch and a second RF port, and coupled in parallel to the RFC port.

7. The RF device of claim 6, further comprising a second shunt ESD dissipation switch coupled in a shunt connection between the second RF port and the second RF switch.

8. The RF device of claim 6, in which the second RF port comprises an ESD pulse port.

9. The RF device of claim 1, integrated in an RF front end (RFFE) module.

10. The RF device of claim 9, in which the RFFE module incorporated in at least one of a music player, a video player, an entertainment unit, a navigation device, a communications device, a personal digital assistant (PDA), a fixed location data unit, a mobile phone, and a portable computer.

11. A method for constructing a radio frequency (RF) device having a symmetric RF electrostatic discharge (ESD) dissipation switch, comprising:
forming a switch field effect transistor (FET) including a gate on an active layer of a substrate;
depositing an oxide layer on the switch FET and on a surface of the active layer of the substrate;
patterning the oxide layer to expose portions of the active layer of the substrate to form a symmetric silicide area block (SAB) on the gate and on exposed portions of the active layer of the substrate proximate sidewalls of the gate;
forming source/drain silicide regions on exposed portions of the active layer of the substrate, adjacent to the symmetric SAB; and
forming source/drain contacts to the source/drain silicide regions.

12. The method of claim 11, in which the symmetric SAB is on a first surface region of the active layer of the substrate, proximate a first sidewall spacer, and on a second surface region of the active layer of the substrate, proximate a second sidewall spacer.

13. The method of claim 11, in which forming the switch FET comprises:
forming a source region in the active layer of the substrate, in which the source silicide region is coupled to the source region and separated from a first sidewall spacer of the gate by a portion of the symmetric SAB on a surface of the active layer of the substrate.

14. The method of claim 11, in which forming the switch FET comprises:
forming a drain region in the active layer of the substrate, in which the drain silicide region is coupled to the drain region and separated from a second sidewall spacer of the gate by a portion of the symmetric SAB on a surface of the active layer of the substrate.

15. The method of claim 11, further comprising:
coupling a first radio frequency (RF) switch in series to a first RF port and in parallel to an RF common (RFC) port; and
coupling the symmetric RF ESD dissipation switch to the RFC port.

16. The method of claim 15, further comprising coupling a first shunt ESD dissipation switch in a shunt connection between the first RF port and the first RF switch.

17. The method of claim 15, further comprising coupling a second RF switch in series to the first RF switch and a second RF port, and in parallel to the RFC port.

18. The method of claim 17, further comprising coupling a second shunt ESD dissipation switch in a shunt connection between the second RF port and the second RF switch, in which the second RF port comprises an ESD pulse port.

19. The method of claim 11, further comprising integrating the RF device in an RF front end (RFFE) module.

20. The method of claim 19, further comprising incorporating the RFFE module in at least one of a music player, a video player, an entertainment unit, a navigation device, a communications device, a personal digital assistant (PDA), a fixed location data unit, a mobile phone, and a portable computer.
